(19) United States
(12) Patent Application Publication
(10) Pub. No.: US 2025/0201311 A1
(43) Pub. Date: Jun. 19, 2025

(54) REUSING PARTIALLY FILLED SUPERBLOCKS FOR PROGRAMMING

(71) Applicant: Micron Technology, Inc., Boise, ID (US)

(72) Inventors: Tawalin Opastrakoon, Boise, ID (US); Michael G. Miller, Boise, ID (US); Gary F. Besinga, Boise, ID (US); Che Chen, Boise, ID (US)

(21) Appl. No.: 18/937,271

(22) Filed: Nov. 5, 2024

Related U.S. Application Data
(60) Provisional application No. 63/610,086, filed on Dec. 14, 2023.

(51) Int. Cl. G11C 16/10; G11C 16/08; G11C 16/32

(52) U.S. Cl. CPC G11C 16/102; G11C 16/08; G11C 16/32

(57) ABSTRACT

A system comprising a memory device and a processing device, operatively coupled to the memory device, to perform operations including initiating a programming operation to write data to a set of pages of a superblock of the memory device, determining whether to terminate the programming operation, in response to determining to terminate the programming operation, causing the superblock to be closed to obtain a partially filled superblock comprising a set of closed pages, causing dummy data to be written to a first subset of closed pages of the set of closed pages to obtain a set of dummy pages, and causing a second subset of closed pages of the set of closed pages to be reopened for programming to obtain a set of reopened pages.

### CROSS-REFERENCE TO RELATED APPLICATION(S)

The present application claims priority to U.S. Provisional Patent Application No. 63/610,086, filed on Dec. 14, 2023 and entitled “REUSING PARTIALLY FILLED SUPERBLOCKS FOR PROGRAMMING”, the entire contents of which are hereby incorporated by reference herein.

### TECHNICAL FIELD

Embodiments of the disclosure relate generally to memory sub-systems, and more specifically, relate to reusing partially filled superblocks in a memory sub-system for programming.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

FIG. 1 illustrates an example computing system that includes a memory sub-system, in accordance with some embodiments of the present disclosure.

FIGS. 2A-2C are diagrams illustrating example methods for reusing partially filled superblocks for programming, in accordance with some embodiments of the present disclosure.

FIG. 3 is a flow diagram of example methods for reusing partially filled superblocks for programming, in accordance with some embodiments of the present disclosure.

FIG. 4 is a block diagram of an example computer system in which embodiments of the present disclosure may operate.

### DETAILED DESCRIPTION

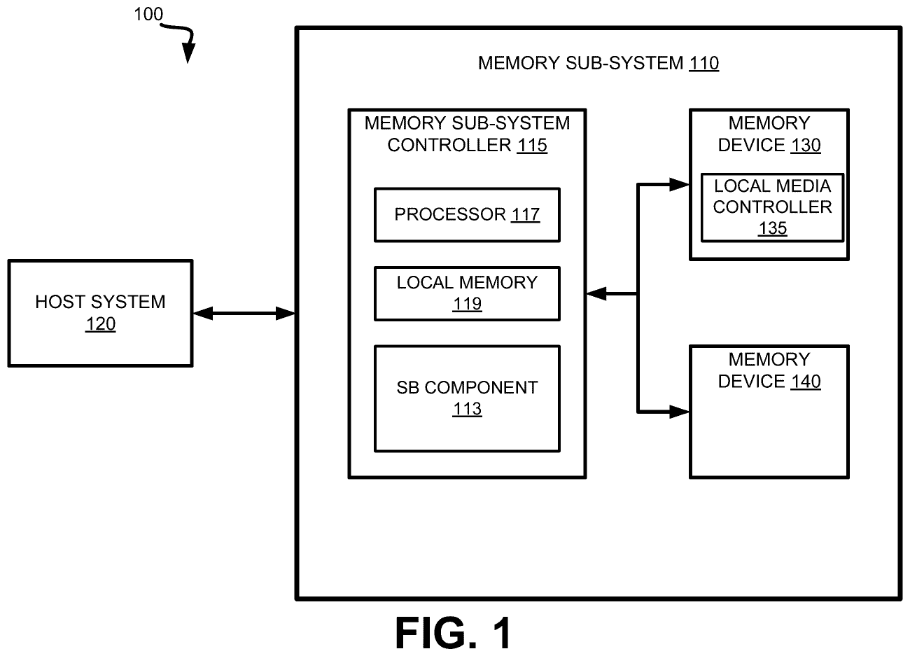

Aspects of the present disclosure are directed to reusing partially filled superblocks in a memory sub-system for programming. A memory sub-system can be a storage device, a memory module, or a combination of a storage device and memory module. Examples of storage devices and memory modules are described below in conjunction with FIG. 1. In general, a host system can utilize a memory sub-system that includes one or more components, such as memory devices that store data. The host system can provide data to be stored at the memory sub-system and can request data to be retrieved from the memory sub-system.

A memory sub-system can include high density non-volatile memory devices where retention of data is desired when no power is supplied to the memory device. One example of non-volatile memory devices is a negative-and (NAND) memory device. Other examples of non-volatile memory devices are described below in conjunction with FIG. 1. A non-volatile memory device is a package of one or more dies. Each die can consist of one or more planes. For some types of non-volatile memory devices (e.g., NAND devices), each plane consists of a set of physical blocks. Each block consists of a set of pages. Each page consists of a set of memory cells (“cells”). A cell is an electronic circuit that stores information. Depending on the cell type, a cell can store one or more bits of binary information, and has various logic states that correlate to the number of bits being stored. The logic states can be represented by binary values, such as “0” and “1”, or combinations of such values.

A memory device can include multiple bits arranged in a two-dimensional grid. Memory cells are formed onto a silicon wafer in an array of columns (also hereinafter referred to as bitlines) and rows (also hereinafter referred to as wordlines). A wordline can refer to one or more rows of memory cells of a memory device that are used with one or more bitlines to generate the address of each of the memory cells. The intersection of a bitline and wordline constitutes the address of the memory cell. A block hereinafter refers to a unit of the memory device used to store data and can include a group of memory cells, a wordline group, a wordline, or individual memory cells. One or more blocks can be grouped together to form a plane of the memory device in order to allow concurrent operations to take place on each plane. The memory device can include circuitry that performs concurrent memory page accesses of two or more memory planes. For example, the memory device can include a respective access line driver circuit and power circuit for each plane of the memory device to facilitate concurrent access of pages of two or more memory planes, including different page types.

Data operations can be performed by the memory sub-system. The data operations can be host-initiated operations. For example, the host system can initiate a data operation (e.g., write, read, erase, etc.) on a memory sub-system. The host system can send access requests (e.g., write command, read command) to the memory sub-system, such as to store data on a memory device at the memory sub-system and to read data from the memory device on the memory sub-system. The data to be read or written, as specified by a host request, is hereinafter referred to as “host data”. A host request can include logical address information (e.g., logical block address (LBA), namespace) for the host data, which is the location the host system associates with the host data. The logical address information (e.g., LBA, namespace) can be part of metadata for the host data. Metadata can also include error handling data (e.g., ECC codeword, parity code), data version (e.g. used to distinguish age of data written), valid bitmap (which LBAs or logical transfer units contain valid data), etc.

A memory cell (“cell”) can be programmed (written to) by applying a certain voltage to the cell, which results in an electric charge being held by the cell. For example, a voltage signal V_{CG} that can be applied to a control electrode of the cell to open the cell to the flow of electric current across the cell, between a source electrode and a drain electrode. More specifically, for each individual cell (having a charge Q stored thereon) there can be a threshold control gate voltage V_{T} (herein also referred to as the “threshold voltage” or simply as “threshold”) such that the source-drain electric current is low for the control gate voltage (V_{CG}) being below the threshold voltage, V_{CG}<V_{T}. The current increases substantially once the control gate voltage has exceeded the threshold voltage, V_{CG}>V_{T}. Because the actual geometry of the electrodes and gates varies from cell to cell, the threshold voltages can be different even for cells implemented on the same die. The cells can, therefore, be characterized by a distribution P of the threshold voltages, P(Q, V_{T})=dW/dV_{T}, where dW represents the probability that any given cell has its threshold voltage within the interval [V_{T},V_{T}+dV_{T}] when charge Q is placed on the cell.

A memory device can have distributions P (Q, V_{T}) that are narrow compared with the working range of control voltages tolerated by the cells of the device. Accordingly, multiple non-overlapping distributions P (Qₖ, V_{T}) (“valleys”) can be fit into the working range allowing for storage and reliable detection of multiple values of the charge Qₖ, k=1, 2, 3. . . . The distributions (valleys) are interspersed with voltage intervals (“valley margins”) where none (or very few) of the cells of the memory device have their threshold voltages. Such valley margins can, therefore, be used to separate various charge states Qₖ—the logical state of the cell can be determined by detecting, during a read operation, between which two valley margins the respective threshold voltage V_{T} of the cell resides. Specifically, the read operation can be performed by comparing the measured threshold voltage V_{T} exhibited by a cell to one or more reference voltage levels corresponding to known valley margins (e.g., centers of the margins).

A memory device can include multiple cells, each of which can store, depending on the type of cell, one or more bits of information. One type of cell is a single level cell (SLC), which stores 1 bit per cell and defines 2 logical states (“states”) (“1” or “L0” and “0” or “L1”) each corresponding to a respective V_{T} level. For example, the “1” state can be an erased state and the “0” state can be a programmed state (L1). Another type of cell is a multi-level cell (MLC), which stores 2 bits per cell and defines 4 states (“11” or “L0”, “10” or “L1”, “01” or “L2” and “00” or “L3”) each corresponding to a respective V_{T} level. For example, the “11” state can be an erased state and the “01”, “10” and “00” states can each be a respective programmed state. Another type of cell is a triple level cell (TLC), which stores 3 bits per cell and defines 8 states (“111” or “L0”, “110” or “L1”, “101” or “L2”, “100” or “L3”, “011” or “L4”, “010” or “L5”,“001” or “L6”, and “000” or “L7”) each corresponding to a respective V_{T} level. For example, the “111” state can be an erased state and each of the other states can be a respective programmed state. Another type of a cell is a quad-level cell (QLC), which stores 4 bits per cell and defines 16 states L0-L15, where L0 corresponds to “1111” and L15 corresponds to “0000”. Another type of cell is a penta-level cell (PLC), which stores 5 bits per cell and defines 32 states. Other types of cells are also contemplated. Thus, an n-level cell can use 2″ levels of charge to store n bits. A memory device can include one or more arrays of memory cells such as SLCs, MLCs, TLCs, QLCs, PLCs, etc. or any combination of such. For example, a memory device can include an SLC portion, and an MLC portion, a TLC portion, a QLC portion, or a PLC portion of memory cells.

Due to the phenomenon known as slow charge loss, the threshold voltage of a cell changes in time as the electric charge of the cell is degrading, which is referred to as “temporal voltage shift” (since the degrading electric charge causes the voltage distributions to shift along the voltage axis towards lower voltage levels). The threshold voltage can change rapidly at first (immediately after the memory cell was programmed), and then slow down in an approximately logarithmic linear fashion with respect to the time elapsed since the cell programming event. Accordingly, failure to mitigate the temporal voltage shift caused by the slow charge loss can result in the increased bit error rate in read operations. However, various common implementations either fail to adequately address the temporal voltage shift or employ inefficient strategies resulting in high bit error rates and/or exhibiting other shortcomings.

In some implementations, a controller of a memory sub-system utilizes a data striping scheme, according to which each data payload (e.g., user data) utilizes multiple dies of a memory device (e.g., NAND type flash memory devices). One example of a memory sub-system is a solid-state drive (SSD). Each payload can be distributed through a subset of dies, while the remaining one or more dies are used to store error correction information (e.g., parity bits). A set of blocks distributed across a set of dies of a memory device using a data striping scheme is referred to herein as a “superblock.” In some cases, a superblock spans all (or at least a subset of) the dice within a memory device. A superblock can contain multiple blocks from a single die, such as one block per plane. The programming and erasing of data of a superblock can be managed on a superblock basis or other granularity of superpages. A superpage is a page programmed to multiple dies as a lowest addressable unit of memory. A superpage can include one page per plane from multiple dies, where the page numbers are the same.

To write host data to pages of a superblock, a controller can identify a superblock including a set of blocks that is available for programming, and initiate a programming operation to write the host data to a set of pages of the superblock. More specifically, the programming operation can write host data to an open block of the set of blocks. An open block refers to a block that is open for programming. An open block can be an empty block or a partially filled block. An open page refers to an empty page of a block that can be programmed with host data (e.g., a programmable page). A programmed page refers to a page of a block that is programmed with host data.

During the programming operation, the controller can identify a condition that causes the programming operation to be terminated before the superblock is completely filled with data (e.g., before every page of the superblock is programmed with data). One example of a condition is a SCL condition to address SCL, which can impact the integrity and reliability of data stored in the programmed page(s), by preserving uniform characteristics and/or behavior across the superblock (e.g. V_{T} placement and/or V_{T} shift). For example, the controller can terminate the programming operation in response to determining that an amount of time that has elapsed from when the programming operation was initiated (e.g., the initial page of the superblock was programmed) exceeds a threshold amount of time. Illustratively, the threshold amount of time can be about one hour, and the controller can terminate the programming operation after one hour from when the programming operation was initiated (e.g., one hour from when the initial page of the superblock was programmed). However, the threshold amount of time can be any suitable amount of time in accordance with implementations described herein.

The controller can terminate the programming operation in response to identifying the condition. Terminating the programming operation can include closing the superblock by closing any empty (e.g., non-programmed) pages for programming. Causing the superblock to be closed can include updating a table to change the status of the superblock from open to closed (e.g., updating a bit). A closed page refers to an empty page that cannot be programmed with host data (e.g., a non-programmable page). Accordingly, if there is insufficient host data to fill a superblock before identifying the condition, then the controller may be forced to prematurely close the superblock. The termination of the programming operation can result in a partially programmed superblock. A block of a partially programmed superblock can include a set of programmed pages and a set of closed pages.

The controller can initiate garbage collection to cause programmed data from the set of programmed pages to be migrated to another superblock, and to cause the programmed data of the partially filled superblock to be invalidated. Typically, the controller can cause an entirety of the superblock to be erased (e.g., each page of the superblock), so that the superblock can be reused for programming starting from an initial page (e.g., page₀).

The erase operation causes the number of program/erase (P/E) cycles of a superblock, and thus a block of the superblock, to be incremented by one. A block, however, can have a finite number of P/E cycles in which data integrity and reliability may be guaranteed. Additionally, when the pages of a partially filled superblock are erased during garbage collection, the partially filled superblock is not being used effectively for data storage and the memory sub-system will not be able to increase the total bytes written (TBW) of the host data.

Aspects of the present disclosure address the above and other deficiencies by enabling partially filled superblocks to be reused for programming. As described above, a controller described herein can initiate a programming operation to a superblock, identify a condition to cause the termination of the programming operation (e.g., SCL condition), and terminate the programming operation upon identifying a condition, which results in a partially filled superblock including a set of programmed pages and a set of closed pages.

Instead of migrating programmed data of the set of programmed pages to another block and then initiating an erase operation to erase the partially filled superblock, the controller can cause a portion of closed pages of the partially filled superblock to be reopened for programming after migrating the programmed data. Accordingly, the controller can re-initiate the programming operation to write data to the partially filled superblock.

To enable the partially filled superblock to be reopened for programming, the controller can cause a first subset of closed pages of the set of closed pages to be programmed with dummy data (e.g., pad with dummy data) to generate a set of dummy pages. In some embodiments, causing the first subset of closed pages to be programmed with dummy data to generate the set of dummy pages includes causing dummy data to be written to at least one page associated with at least one wordline of the partially filled superblock. For example, the at least one wordline can include a last written wordline of the partially filled superblock. The last written wordline of the partially filled superblock is a wordline of a block of the partially filled superblock that includes the last programmed page prior to the termination of the programming operation. The last written wordline can be associated with a combination of programmed pages and closed pages, and programming the first subset of closed pages with dummy data to generate the set of dummy pages can include programming the closed pages of the last written wordline with dummy data.

The controller can reopen the partially filled superblock by reopening a second subset of closed pages of the set of closed pages for programming, resulting in a set of reopened pages. In other words, each closed page of the second subset of closed pages is converted into an empty page of the set of reopened pages that is available for programming. More specifically, the set of reopened pages can include each closed page of the partially filled superblock that was not programmed with dummy data. For example, the initial page of the set of reopened pages can include the initial page corresponding to the next wordline following the last written wordline.

After reopening the partially filled superblock, the controller can then initiate a programming operation to write data to the set of reopened pages. For example, the programming operation can begin at the initial page corresponding to the next wordline following the last written wordline. Since the superblock was not erased as part the reopening process, the number of P/E cycles of the superblock is not incremented by one. Accordingly, since the number of P/E/cycles remains unaffected by the reopening process, the lifespan of the superblock can be extended and the TBW of host data can be increased. Further details regarding the operations performed by the memory sub-system controller will be described below with reference to FIGS. 1-4.

Advantages of the present disclosure include, but are not limited to, improved memory device performance and QoS. For example, embodiments described herein can be used to extend the lifespan of a superblock and improve the TBW to a memory device.

FIG. 1 illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a combination of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to multiple memory sub-systems 110 of different types. FIG. 1 illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access components (e.g., memory devices 130) when the memory sub-system 110 is coupled with the host system 120 by the physical host interface (e.g., PCIe bus). The physical host interface can provide an interface for passing control, address, data, and other signals between the memory sub-system 110 and the host system 120. FIG. 1 illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include a negative-and (NAND) type flash memory and write-in-place memory, such as a three-dimensional cross-point (“3D cross-point”) memory device, which is a cross-point array of non-volatile memory cells. A cross-point array of non-volatile memory cells can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130 can include one or more arrays of memory cells. One type of memory cell, for example, single level cells (SLC) can store one bit per cell. Other types of memory cells, such as multi-level cells (MLCs), triple level cells (TLCs), quad-level cells (QLCs), and penta-level cells (PLCs) can store multiple bits per cell. In some embodiments, each of the memory devices 130 can include one or more arrays of memory cells such as SLCs, MLCs, TLCs, QLCs, PLCs or any combination of such. In some embodiments, a particular memory device can include an SLC portion, and an MLC portion, a TLC portion, a QLC portion, or a PLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), negative-or (NOR) flash memory, or electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processing device, which includes one or more processors (e.g., processor 117), configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1 has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., a logical block address (LBA), namespace) and a physical address (e.g., physical block address) that are associated with the memory devices 130. The memory sub-system controller 115 can further include host interface circuitry to communicate with the host system 120 via the physical host interface. The host interface circuitry can convert the commands received from the host system 120 into command instructions to access the memory devices 130 as well as convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, memory sub-system 110 is a managed memory device, which is a raw memory device 130 having control logic (e.g., local controller 132) on the die and a controller (e.g., memory sub-system controller 115) for media management within the same memory device package. An example of a managed memory device is a managed NAND (MNAND) device.

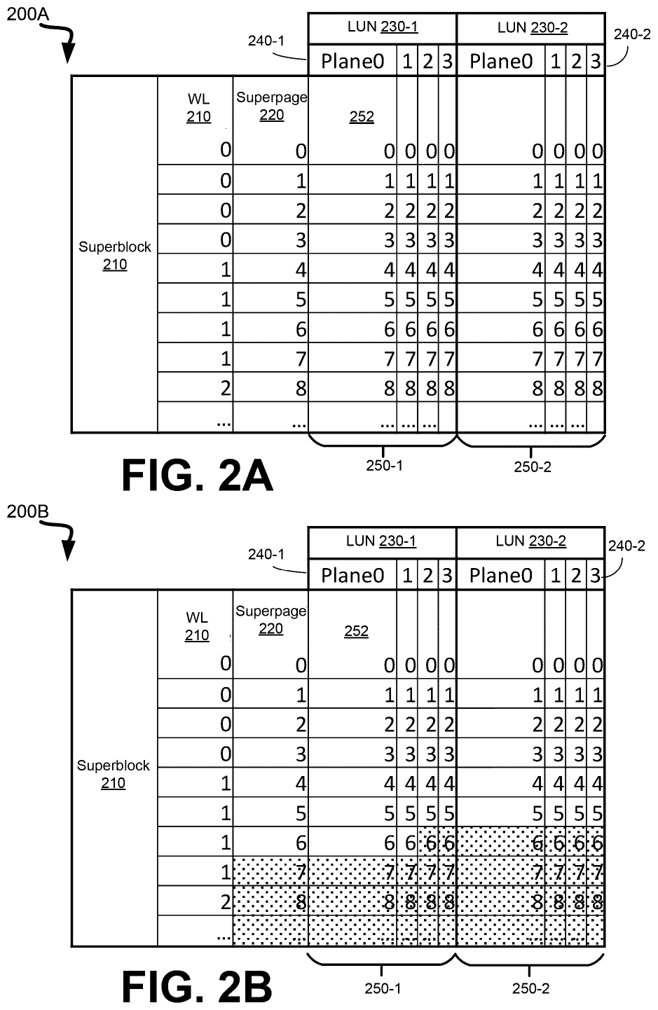

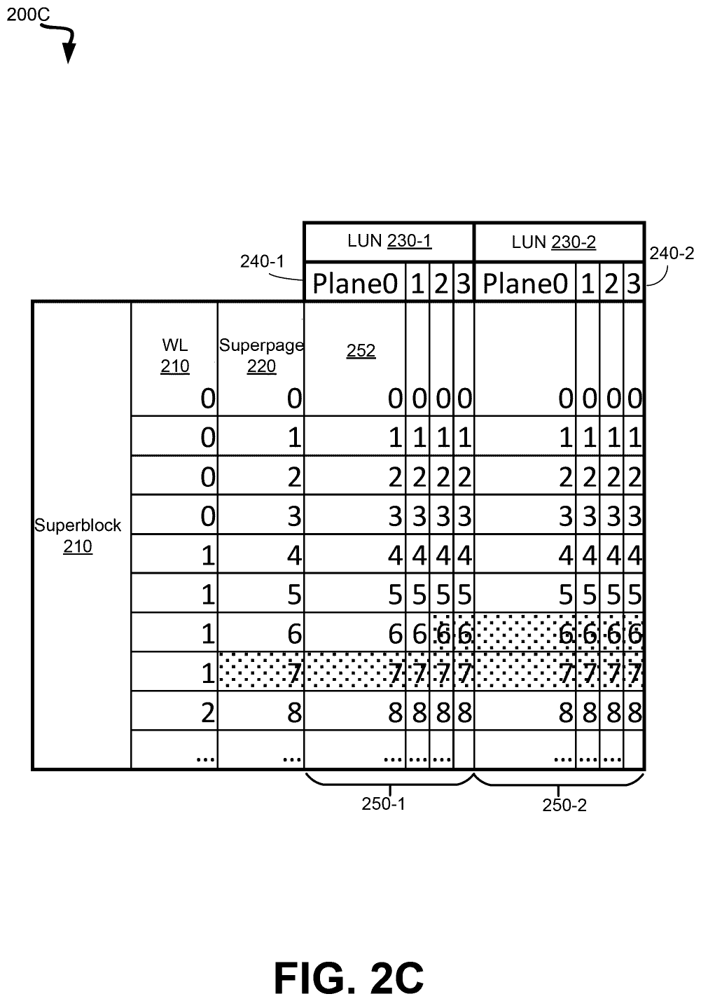

The memory sub-system 110 includes a superblock (SB) component 113. SB component 113 can implement functionality for reusing partially filled superblocks for programming. In some embodiments, the memory sub-system controller 115 includes at least a portion of the SB component 113. In some embodiments, the SB component 113 is part of the host system 120, an application, or an operating system. In other embodiments, local media controller 135 includes at least a portion of SB component 113 and is configured to perform the functionality. Further details regarding operations implemented by SB component 113 to implement the functionality will now be described in further detail below with reference to FIGS. 2A-4.

FIGS. 2A-2C are diagrams illustrating example methods for reusing partially filled superblocks for programming, in accordance with some embodiments of the present disclosure. For example, FIG. 2A is a diagram 200A of superblock 210 having associated set of wordlines (WLs) 210, set of superpages 220, a set of LUNS including LUN 230-1 and LUN 230-2, set of planes 240-1 of LUN 230-1 and set of planes 240-2 of LUN 230-2, and set of pages 250-1 of LUN 230-1 and set of pages 250-2. Each WL can correspond to a set of superpages. As shown, each WL corresponds to four super pages. For example, WL₀ corresponds to superpage₀, superpage₁, superpage₂ and superpage₃, WL₁ corresponds to superpage₄, superpage₅, superpage₆ and superpage₇, etc. Additionally, each superpage represents a grouping of pages having the same page index across the set of LUNS (e.g., LUN 230-1 and LUN 230-2). For example, superpage₀ represents a grouping of page₀ across the sets of LUNS, superpage₁ represents a grouping of page₁ across the sets of LUNS, etc.

More specifically, diagram 200A illustrates superblock 210 as an empty superblock prior to host data being programmed to the pages of superblock 210. For example, set of WLs 210 can include WL₀, WL₁, WL₂, etc. Set of planes 240-1 can include first plane₀, first plane₁, first plane₂, first plane₃, etc. Set of planes 240-2 can include second plane₀, second plane₁, second plane₂, second plane₃, etc. Each page of set of pages 250-1 corresponds to a page of a respective plane of set of planes 240-1. Each page of set of pages 250-2 corresponds to a page of a respective plane of set of planes 240-2.

In this example, it is assumed that a controller (e.g., memory sub-system controller 115 of FIG. 1) has initiated a programming operation to write data to the pages of superblock 210. FIG. 2B is a diagram 200B of superblock 210 after the controller terminates the programming operation in response to identifying a condition (e.g., SCL condition). For example, the controller can terminate the programming operation in response to determining that an amount of time that has elapsed from when the programming operation to superblock 210 was initiated (e.g., an initial page of superblock 210 was programmed) exceeds a threshold amount of time. For example, the initial page can be page₀ 252. Illustratively, the threshold amount of time can be about one hour, and the controller can terminate the programming operation after one hour from when the programming operation was initiated (e.g., one hour from when the initial page of the superblock was programmed). However, the threshold amount of time can be any suitable amount of time in accordance with implementations described herein.

More specifically, diagram 200B illustrates superblock 210 as a partially filled superblock. Superblock 210 includes programmed pages among sets of pages 250-1 and 250-2 that were programmed with host data at the time of termination of the programming operation. Additionally, superblock 210 includes closed pages among sets of pages 250-1 and 250-2 that remained empty at the time of termination of the programming operation, and were thus closed for programming by the controller. The closed pages are identified by stippling in FIG. 2B. For example, the programmed pages span from page₀ of plane₀ of LUN 230-1 to page₆ of plane₁ of LUN 230-1, and the closed pages start from page₆ of plane₂ of LUN 230-1 (and include the remainder of the pages of superblock 210).

FIG. 2C is a diagram 200C of superblock 210 after the controller has caused a portion of closed pages of superblock 210 to be reopened for programming (e.g., after migrating the programmed data of the programmed pages). To enable superblock 210 to be reopened for programming, the controller can cause a first portion of the closed pages of superblock 210 to be programmed with dummy data (e.g., pad with dummy data) to generate dummy pages, as indicated by the striping. In some embodiments, causing the first portion of the closed pages of superblock 210 to be programmed with dummy data includes causing dummy data to be written to at least one wordline of superblock 210. For example, the at least one wordline can include a last written wordline of superblock 210. The last written wordline of superblock 210 is a wordline of a block of superblock 210 that includes the last programmed page of superblock 210 prior to the termination of the programming operation. The last written wordline of superblock 210 can be associated with a combination of programmed pages and closed pages of superblock 210, and programming the first portion of the closed pages of superblock 210 with dummy data can include programming the closed pages of the last written wordline of superblock 210 with dummy data. In this illustrative example, the last written wordline of superblock 210 is WL₁ since the last programmed page of superblock 210 is page₆ of plane₁ of LUN 230-1, which corresponds to WL₁). Thus, the closed pages of WL₁ following page₆ of plane₁ of LUN 230-1 (spanning from page₆ of plane₂ of LUN 230-1 to page₇ of plane₃ of LUN 230-2) are programmed with dummy data.

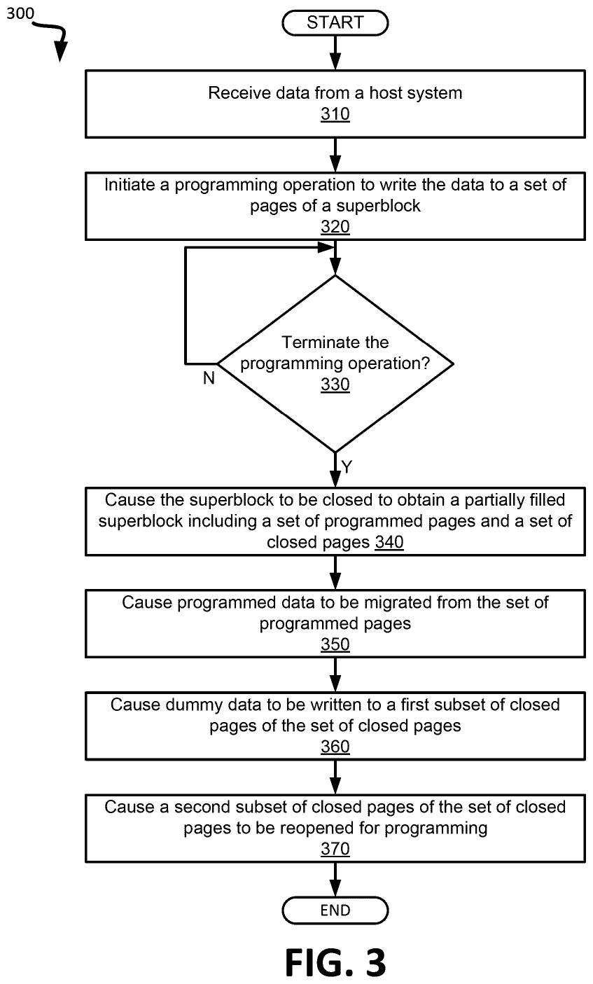

The controller can reopen superblock 210 for further programming by reopening a second portion of the closed pages of superblock 210 to obtain reopened pages. In other words, each closed page of the second portion of the closed pages of superblock 210 is converted into an empty page of the reopened pages that is available for programming. More specifically, the reopened pages of superblock 210 can include each closed page of superblock 210 that was not programmed with dummy data. For example, the initial page of the reopened pages of superblock 210 can include the initial page corresponding to the next wordline of superblock 210 following the last written wordline of superblock 210. In this illustrative example, the next wordline of superblock 210 is WL₂, such that programming of superblock 210 is reopened beginning with the page₈ group defined by superpage₈. Accordingly, the controller can initiate a programming operation to write data to the reopened pages of superblock 210. Further details regarding the operations described above with reference to FIGS. 2A-2C will now be described in further detail below with reference to FIG. 3.

FIG. 3 is a flow diagram of an example method 300 for reusing partially filled superblocks for programming, in accordance with some embodiments of the present disclosure. Method 300 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, method 300 is performed by the SB component 113 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 310, processing logic receives data from a host system. For example, the host system can correspond to host system 120 of FIG. 1.

At operation 320, processing logic initiates a programming operation to write the data to a set of pages of a superblock of a memory device. For example, the memory device can correspond to memory device 130 of FIG. 1 and the superblock can correspond to superblock 210 of FIG. 2A. More specifically, the programming operation can write host data to open pages of an open block within the superblock. In some embodiments, the superblock is an empty superblock. In some embodiments, the superblock is a partially filled superblock. For example, the set of pages of the superblock can correspond to pages of the superblock that were previously reopened for programming.

At operation 330, processing logic determines whether to terminate the programming operation. More specifically, the programming operation can be terminated prior to writing data to every page of the superblock (e.g., prior to completely filling the superblock). One example of a condition is a SCL condition to address SCL, which can impact the integrity and reliability of data stored in the programmed page(s), by preserving uniform characteristics and/or behavior across the superblock (e.g. V_{T} placement and/or V_{T} shift). For example, determining whether to terminate the programming operation can include determining whether an amount of time that has elapsed from when the programming operation was initiated (e.g., the initial page of the superblock was programmed) exceeds a threshold amount of time. Illustratively, the threshold amount of time can be about one hour, and processing logic can cause the programming operation to be terminated after one hour from when the programming operation was initiated (e.g., one hour from when the initial page of the superblock was programmed). The threshold amount of time, however, can be any suitable amount of time in accordance with embodiments described herein.

If processing logic does not determine to terminate the programming operation, then the programming operation resumes. Otherwise, at operation 340, processing logic causes the superblock to be closed to obtain a partially filled superblock including a set of programmed pages and a set of closed pages. Causing the superblock to be closed can include updating a table to change the status of the superblock from open to closed (e.g., updating a bit). More specifically, the set of closed pages can include each page of the set of pages of the superblock that was empty at the time of termination of the programming operation. For example, the set of closed pages can start from page₆ of plane₁ of LUN 230-1, as described above with reference to FIG. 2B.

At operation 350, processing logic causes programmed data to be migrated from the set of programmed pages. For example, the programmed data can be migrated after the superblock is closed. In some embodiments, the programmed data is migrated in response to closing the superblock. In some embodiments, the programmed data is migrated at any time after the superblock is closed. In some embodiments, causing the programmed data to be migrated includes initiating a garbage collection operation. For example, processing logic can cause the programmed data to be migrated to a set of pages of another superblock that is opened for programming (e.g., an empty superblock).

At operation 360, processing logic causes dummy data to be written to a first subset of closed pages of the set of closed pages (e.g., padding). Writing dummy data to the first subset of closed pages generates a set of dummy pages. In some embodiments, causing the first subset of closed pages to be programmed with dummy data includes causing dummy data to be written to at least one page associated with at least one wordline of the partially filled superblock. For example, the at least one wordline can include a last written wordline of the partially filled superblock. The last written wordline of the partially filled superblock is a wordline of a block of the partially filled superblock that includes the last programmed page prior to the termination of the programming operation. The last written wordline can be associated with a combination of programmed pages and closed pages, and programming the first subset of closed pages with dummy data to generate the set of dummy pages can include programming the closed pages of the last written wordline with dummy data. For example, the last written wordline can correspond to WL₁, the set of programmed pages associated with the last written wordline can correspond to page₄ of plane₁ of LUN 230-1 through page₆ of plane₁ of LUN 230-1, and the set of dummy pages can correspond to page₆ of plane₂ of LUN 230-1 through page₇ of plane₃ of LUN 230-2, as described above with reference to FIG. 2C.

At operation 370, processing logic causes a second subset of closed pages of the set of closed pages to be reopened for programming. Reopening the second subset of closed pages results in a set of reopened pages. In other words, each closed page of the second subset of closed pages is converted into an empty page of the set of reopened pages that is available for programming. More specifically, the second subset of closed pages can include each closed page of the partially filled superblock that was not programmed with dummy data. For example, the initial page of the set of reopened pages can include the initial page corresponding to the next wordline following the last written wordline. For example, the next wordline can correspond to WL₂ and the initial page of the set of reopened pages can correspond to superpage₈, as described above with reference to FIG. 2C.

Processing logic can then initiate a programming operation to write data to the set of reopened pages. For example, the programming operation can begin at the initial page corresponding to the next wordline following the last written wordline. Since the superblock was not erased as part the re-opening process, the number of P/E cycles of the superblock is not incremented by one. Accordingly, since the number of P/E cycles remains unaffected by the re-opening process, the lifespan of the superblock can be extended and the TBW of host data can be increased. Further details regarding operations 310-370 are described above with reference to FIGS. 1-3.

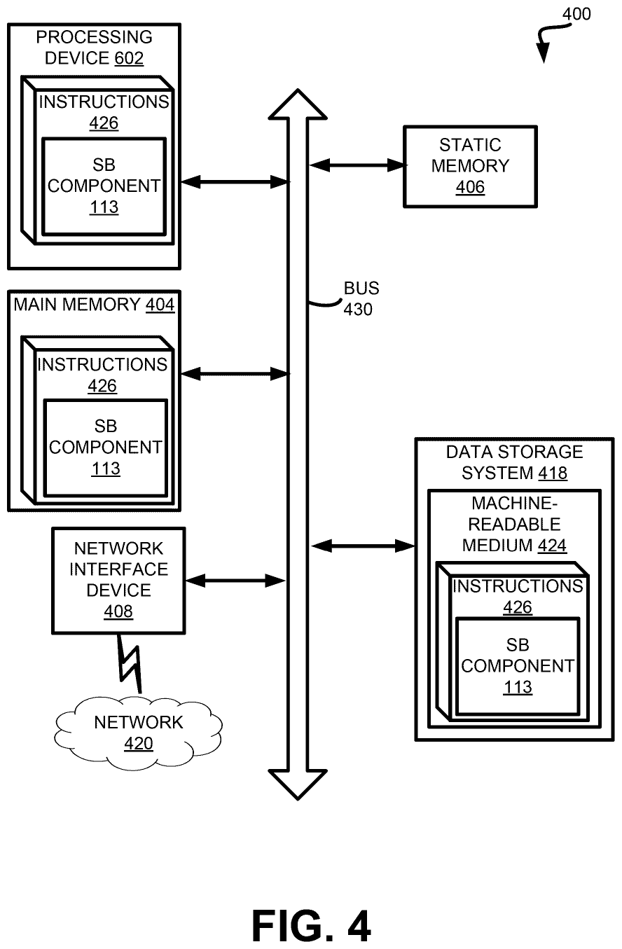

FIG. 4 illustrates an example machine of a computer system 400 within which a set of instructions, for causing the machine to perform any one or more of the methodologies discussed herein, can be executed. In some embodiments, the computer system 400 can correspond to a host system (e.g., the host system 120 of FIG. 1) that includes, is coupled to, or utilizes a memory sub-system (e.g., the memory sub-system 110 of FIG. 1) or can be used to perform the operations of a controller (e.g., to execute an operating system to perform operations corresponding to the SB component 113 of FIG. 1). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 400 includes a processing device 402, a main memory 404 (e.g., read-only memory (ROM), flash memory, dynamic random access memory (DRAM) such as synchronous DRAM (SDRAM) or RDRAM, etc.), a static memory 406 (e.g., flash memory, static random access memory (SRAM), etc.), and a data storage system 418, which communicate with each other via a bus 430.

Processing device 402 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 402 can also be one or more special-purpose processing devices such as an application specific integrated circuit (ASIC), a field programmable gate array (FPGA), a digital signal processor (DSP), network processor, or the like. The processing device 402 is configured to execute instructions 426 for performing the operations and steps discussed herein. The computer system 400 can further include a network interface device 408 to communicate over the network 420.

The data storage system 418 can include a machine-readable storage medium 424 (also known as a computer-readable medium) on which is stored one or more sets of instructions 426 or software embodying any one or more of the methodologies or functions described herein. The instructions 426 can also reside, completely or at least partially, within the main memory 404 and/or within the processing device 402 during execution thereof by the computer system 400, the main memory 404 and the processing device 402 also constituting machine-readable storage media. The machine-readable storage medium 424, data storage system 418, and/or main memory 404 can correspond to the memory sub-system 110 of FIG. 1.

In one embodiment, the instructions 426 include instructions to implement functionality corresponding to an SB component (e.g., the SB component 113 of FIG. 1). While the machine-readable storage medium 424 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A system comprising:
a memory device; and
a processing device, operatively coupled with the memory device, to perform operations comprising:
initiating a programming operation to write data to a set of pages of a superblock of the memory device;
determining whether to terminate the programming operation;
in response to determining to terminate the programming operation, causing the superblock to be closed to obtain a partially filled superblock comprising a set of closed pages;
causing dummy data to be written to a first subset of closed pages of the set of closed pages to obtain a set of dummy pages; and
causing a second subset of closed pages of the set of closed pages to be reopened for programming to obtain a set of reopened pages.

2. The system of claim 1, wherein the operations further comprise causing programmed data to be migrated from a set of programmed pages of the partially filled superblock to a second set of pages of a second superblock.

3. The system of claim 1, wherein the operations further comprise initiating a second programming operation to write second data to the set of reopened pages.

4. The system of claim 1, wherein determining whether to terminate the programming operation comprises determining whether an amount of time that has elapsed from when the programming operation was initiated exceeds a threshold amount of time.

5. The system of claim 1, wherein causing the first subset of closed pages to be programmed with dummy data comprises causing the dummy data to be written to at least one page associated with at least one wordline of the partially filled superblock.

6. The system of claim 5, wherein the at least one page associated with the at least one wordline of the partially filled superblock comprises a last programmed page associated with a last written wordline prior to termination of the programming operation.

7. The system of claim 6, wherein the set of reopened pages further comprises an initial page associated with a next wordline following the last written wordline.

8. A method comprising:
initiating, by a processing device, a programming operation to write data to a set of pages of a superblock of a memory device;
determining, by the processing device, whether to terminate the programming operation;
in response to determining to terminate the programming operation, causing, by the processing device, the superblock to be closed to obtain a partially filled superblock comprising a set of closed pages;
causing, by the processing device, dummy data to be written to a first subset of closed pages of the set of closed pages to obtain a set of dummy pages; and
causing, by the processing device, a second subset of closed pages of the set of closed pages to be reopened for programming to obtain a set of reopened pages.

9. The method of claim 8, further comprising causing, by the processing device, programmed data to be migrated from a set of programmed pages of the partially filled superblock to a second set of pages of a second superblock.

10. The method of claim 8, further comprising initiating, by the processing device, a second programming operation to write second data to the set of reopened pages.

11. The method of claim 8, wherein determining whether to terminate the programming operation comprises determining whether an amount of time that has elapsed from when the programming operation was initiated exceeds a threshold amount of time.

12. The method of claim 8, wherein causing the first subset of closed pages to be programmed with dummy data comprises causing the dummy data to be written to at least one page associated with at least one wordline of the partially filled superblock.

13. The method of claim 12, wherein the at least one page associated with the at least one wordline of the partially filled superblock comprises a last programmed page associated with a last written wordline prior to termination of the programming operation.

14. The method of claim 13, wherein the set of reopened pages further comprises an initial page associated with a next wordline following the last written wordline.

15. A non-transitory computer-readable storage medium comprising instructions that, when executed by a processing device, cause the processing device to perform operations comprising:
initiating a programming operation to write data to a set of pages of a superblock of a memory device;
determining whether to terminate the programming operation;
in response to determining to terminate the programming operation, causing the superblock to be closed to obtain a partially filled superblock comprising a set of closed pages; and
causing dummy data to be written to a first subset of closed pages of the set of closed pages to obtain a set of dummy pages; and
causing a second subset of closed pages of the set of closed pages to be reopened for programming to obtain a set of reopened pages.

16. The non-transitory computer-readable storage medium of claim 15, wherein the operations further comprise causing programmed data to be migrated from a set of programmed pages of the partially filled superblock to a second set of pages of a second superblock.

17. The non-transitory computer-readable storage medium of claim 15, wherein the operations further comprising initiating a second programming operation to write second data to the set of reopened pages.

18. The non-transitory computer-readable storage medium of claim 15, wherein determining whether to terminate the programming operation comprises determining whether an amount of time that has elapsed from when the programming operation was initiated exceeds a threshold amount of time.

19. The non-transitory computer-readable storage medium of claim 15, wherein causing the first subset of closed pages to be programmed with dummy data comprises causing the dummy data to be written to at least one page associated with at least one wordline of the partially filled superblock.

20. The non-transitory computer-readable storage medium of claim 19, wherein the at least one page associated with the at least one wordline of the partially filled superblock comprises a last programmed page associated with a last written wordline prior to termination of the programming operation, and wherein the set of reopened pages further comprises an initial page associated with a next wordline following the last written wordline.
